(19) United States
(12) Patent Application Publication
(10) Pub. No.: US 2025/0355052 A1
(43) Pub. Date: Nov. 20, 2025

(54) ACCURATE COULOMB COUNTING SYSTEM AND STATE OF CHARGE ESTIMATION

(71) Applicant: Nova Semiconductor Inc., San Jose, CA (US)

(72) Inventors: Ahmad Rick ASHRAFZADEH, Morgan Hill, CA (US); Adam John WHITWORTH, Los Gatos, CA (US)

(21) Appl. No.: 19/208,926

(22) Filed: May 15, 2025

Related U.S. Application Data
(60) Provisional application No. 63/648,032, filed on May 15, 2024.

(51) Int. Cl. G01R 31/389; G01R 31/367; G01R 31/3842; G01R 31/396; H01M 10/42

(52) U.S. Cl. CPC G01R 31/389; G01R 31/367; G01R 31/3842; G01R 31/396; H01M 10/425; H01M 2220/20

(57) ABSTRACT

A method for estimating battery impedance and remaining energy in a battery system, including a group of battery cells, includes periodically measuring current and voltages of all battery cells in the group of batter cells for a time period. The method also includes determining a present current value in accordance with averaging the measured current and voltages over the time period. The method further includes detecting a step change in a current based on a comparison of the present current value with one or more previously stored current vales. The method still further includes initiating an impedance measurement event in accordance with validating the step change.

### CROSS-REFERENCE TO RELATED APPLICATION

This application claims priority to U.S. Provisional Patent Application No. 63/648,032, filed on May 15, 2024, and titled “ACCURATE COULOMB COUNTING SYSTEM AND STATE OF CHARGE ESTIMATION,” the disclosure of which is expressly incorporated by reference in its entirety.

### TECHNICAL FIELD

This disclosure relates generally to battery management systems, and, more specifically, to charge and energy estimation techniques for rechargeable battery packs.

### DESCRIPTION OF THE RELATED TECHNOLOGY

Coulomb counting, also referred to as a charge accumulation technique, is a technique for measuring the flow of electrons through a conductor. Coulomb counting may be used to estimate the remaining charge in a battery. Specifically, a total number of coulombs that enter the battery may be indicative of the charge available for use. Measuring the remaining charge is an aspect of battery-operated devices, such as electric vehicles and notebook computers. The remaining charge correlates with operational parameters, such as driving range and battery life. Thus, having an accurate coulomb counting system may improve device performance and user satisfaction in rechargeable battery-powered applications.

The flow of electrons through a conductor measurement does not need to precisely represent the standard definition of a coulomb, where one coulomb is one ampere-second of electric charge. Instead, any unit can be used to quantify a charge, as long as the unit maintains a consistent linear relationship with the actual charge accumulation. The unit may also be consistently applied to measure usage and estimate the remaining operational time. Absolute accuracy to the coulomb is not a specified aspect of quantifying charge. Instead, a specified aspect of quantifying charge is maintaining consistent proportionality to ensure reliable measurements and calculations.

### SUMMARY

Various aspects of the present disclosure is directed to systems and methods for estimating battery impedance and remaining energy in a battery system comprising a group of battery cells. Accurate estimation of impedance and energy is essential for reliable state-of-charge (SOC) determination, battery health monitoring, and runtime prediction across a wide range of battery-powered applications.

In some examples, a method is provided for estimating battery impedance and remaining energy. The method includes simultaneously measuring current and voltages of all battery cells in a battery system over a defined time period. During this measurement period, the system determines a present current value by averaging the measured current and voltages over the same time interval to obtain a consistent, time-aligned dataset. The method further includes detecting a step change in current by comparing the present current value with one or more previously stored current values. A step change may indicate a load transient or charging event that creates suitable conditions for impedance analysis. Upon detecting and validating the step change, the method initiates an impedance measurement event. The validation of the step change may be based on a predefined current threshold, along with optional evaluation of additional conditions such as voltage range, battery temperature, or state of charge. Once validated, the impedance of each battery cell can be determined by comparing voltage and current changes, and the resulting impedance values can be used for battery health tracking, aging detection, and correction of energy and SOC estimation.

In other examples, a battery monitoring system is disclosed for performing the above method. The system includes a current sensor configured to measure current flowing through the battery system, and a group of voltage sensors, each configured to measure the voltage of a respective battery cell in the system. The system also includes one or more memory units for storing the measured current and voltage values, and a control circuit. The control circuit is configured to periodically measure voltage and current data, calculate averaged current values, detect a step change in current, and validate conditions for initiating an impedance measurement event.

### BRIEF DESCRIPTION OF THE DRAWINGS

So that features of the present disclosure can be understood in detail, a particular description may be had by reference to aspects, some of which are illustrated in the appended drawings. It is to be noted, however, that the appended drawings illustrate only certain aspects of this disclosure and are therefore not to be considered limiting of its scope, for the description may admit to other equally effective aspects. The same reference numbers in different drawings may identify the same or similar elements.

FIG. 1 is a block diagram illustrating an example of a four-cell battery management system, in accordance with various aspects of the present disclosure.

FIG. 2 is a block diagram illustrating an example of a sample time generation circuit configured to produce a timing signal used to synchronize sampling across multiple Voltage-Controlled Oscillator (VCO)-based measurement channels, in accordance with various aspects of the present disclosure.

FIG. 3 is a block diagram illustrating an example of a measurement subsystem that uses a matched VCO-based sample time generator to coordinate the timing of frequency-based voltage measurements, in accordance with various aspects of the present disclosure.

FIG. 4 illustrates an example of a VCO-based charge accumulation subsystem configured to implement such periodic recalibration and bidirectional charge detection, in accordance with various aspects of the present disclosure.

FIG. 5 illustrates a high-side coulomb counting and calibration architecture, in accordance with various aspects of the present disclosure.

FIG. 6 illustrates an example of partitioning a battery's state of charge (SOC) versus open circuit voltage (OCV) profile, in accordance with various aspects of the present disclosure.

FIG. 7 illustrates representative use cases for a battery management system (BMS), in accordance with various aspects of the present disclosure.

FIG. 8 is a block diagram illustrating an example of a process for estimating battery impedance and remaining energy in a battery system including a group of battery cells, in accordance with various aspects of the present disclosure.

### DETAILED DESCRIPTION

Various aspects of the disclosure are described more fully below with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings, one skilled in the art should appreciate that the scope of the disclosure is intended to cover any aspect of the disclosure, whether implemented independently of or combined with any other aspect of the disclosure. For example, an apparatus may be implemented or a method may be practiced using any number of the aspects set forth. In addition, the scope of the disclosure is intended to cover such an apparatus or method, which is practiced using other structure, functionality, or structure and functionality in addition to or other than the various aspects of the disclosure set forth. It should be understood that any aspect of the disclosure disclosed may be embodied by one or more elements of a claim.

Several aspects of battery management systems will now be presented with reference to various apparatuses and techniques. These apparatuses and techniques will be described in the following detailed description and illustrated in the accompanying drawings by various blocks, modules, components, circuits, steps, processes, algorithms, and/or the like (collectively referred to as “elements”). These elements may be implemented using hardware, software, or combinations thereof. Whether such elements are implemented as hardware or software depends upon the particular application and design constraints imposed on the overall system.

Various aspects of the present disclosure incorporate by reference the various aspects from U.S. Pat. Nos. 10,964,928 and 11,906,597, as well as U.S. application Ser. No. 18/407,268, in addition to any continuation applications, divisional, applications, or continuation-in-parts thereof.

As discussed, coulomb counting, also referred to as a charge accumulation technique, is a technique for measuring the flow of electrons through a conductor. Coulomb counting may be used to estimate the remaining charge in a battery. Specifically, a total number of coulombs that enter the battery may be indicative of the charge available for use. Measuring the remaining charge is an aspect of battery-operated devices, such as electric vehicles and notebook computers. The remaining charge correlates with operational parameters, such as driving range and battery life. Thus, having an accurate coulomb counting system may improve device performance and user satisfaction in rechargeable battery-powered applications.

The flow of electrons through a conductor measurement does not need to precisely represent the standard definition of a coulomb, where one coulomb is one ampere-second of electric charge. Instead, any unit can be used to quantify a charge, as long as the unit maintains a consistent linear relationship with the actual charge. The unit may also be consistently applied for measuring usage and estimating the remaining operational time. Absolute accuracy to the coulomb is not a specified aspect of quantifying charge. Instead, a specified aspect of quantifying charge is maintaining consistent proportionality to ensure reliable measurements and calculations.

Current measurement, an aspect of coulomb counting, offers a snapshot of the current flowing through a conductor at a specific moment. However, current measurement alone may not accurately represent the total accumulation of charge over time. Conventional techniques attempt to represent the total accumulation of charge over time by averaging the measured current and implementing time sampling intervals to estimate charge integration. Unfortunately, averaging the measured current and implementing time sampling intervals to estimate charge integration is prone to errors due to inaccuracies in averaging and fluctuations in sampling intervals. These errors can cause incorrect assessments of charge accumulation, especially when the current flow is variable or subject to noise. As a result, systems that average measured current and implement time sampling intervals to estimate charge integration often provide a less accurate representation of charge accumulation, potentially leading to erroneous conclusions about battery capacity, remaining charge, and remaining time.

Although coulomb counting provides a useful indication of a battery's state of charge (SOC), it does not by itself provide an accurate determination of the remaining energy or usage capacity of the battery. To accurately assess remaining energy, both current and voltage must be considered, as energy is represented by the integral of power over time, and power is defined as the product of current and voltage. Because a battery's open circuit voltage (OCV) varies as a function of its state of charge, typically decreasing as the battery discharges, a voltage profile correlating OCV with SOC is needed to estimate remaining energy from the measured charge.

In regulated power systems, a load may draw a fixed power level, such that the current draw varies inversely with fluctuations in the input voltage to maintain consistent output power. While this assumption simplifies power estimation, actual system efficiency may vary with input voltage, which can lead to variations in power usage. However, for the purposes of energy estimation within a defined voltage operating range, system efficiency may be assumed to remain substantially constant, enabling a reliable approximation of energy usage based on current and voltage measurements.

Various aspects of the present disclosure are directed to yielding a more accurate representation of the actual coulomb. In some examples, an improved approach to charge accumulation is considered. Conventional techniques rely on time-based sampling and averaging. In contrast, aspects of the present disclosure inherently accumulate charge, providing a more continuous and reliable measurement. By not implementing discrete time-based sampling, this topology removes a significant source of error, allowing for a more consistent and uninterrupted accumulation of charge.

The improved approach to charge accumulation can account for charge flowing in both directions. For example, using an inherent accumulation technique, charge accumulated during battery charging can be offset by charge subtracted during battery discharge, leading to a more precise estimation of the battery's remaining charge. This inherent accumulation technique provides an improvement in accuracy over conventional techniques, making the inherent accumulation technique particularly valuable in applications requiring precise battery management and monitoring.

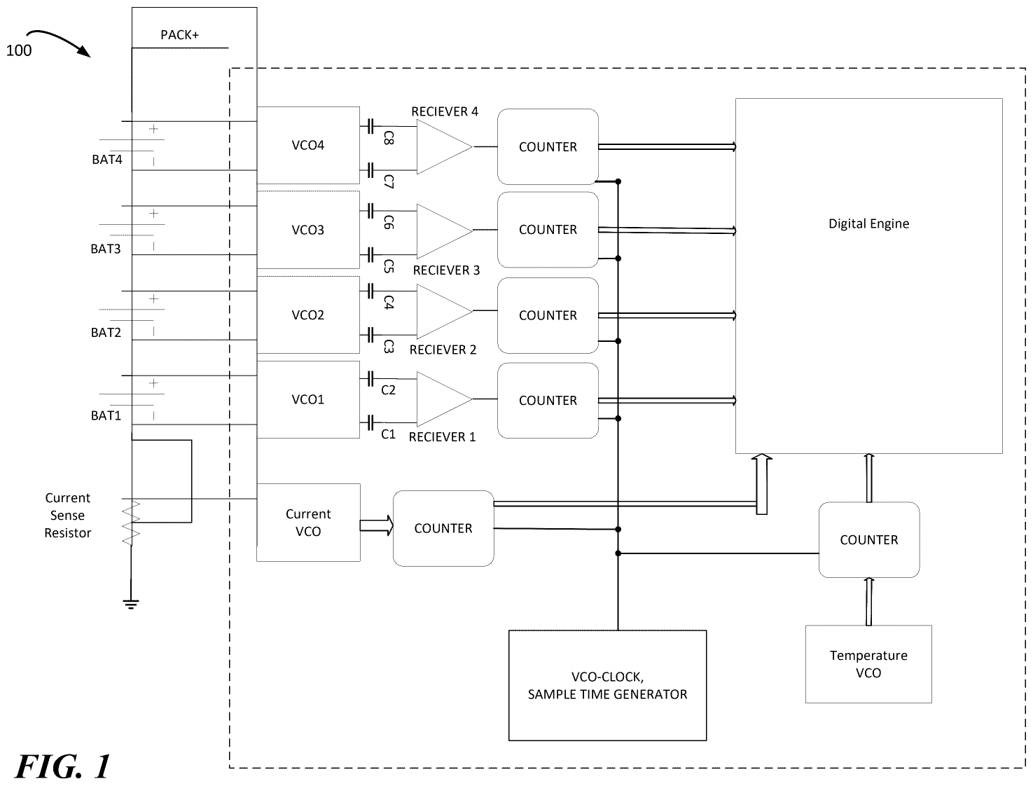

FIG. 1 is a block diagram illustrating an example of a four-cell battery management system 100, in accordance with various aspects of the present disclosure. The system 100 includes a series of battery cells labeled BAT1 through BAT4, connected in series between PACK− (not shown in the example of FIG. 1) and PACK+. Each battery cell may be individually monitored using a respective Voltage-Controlled Oscillator (VCO), labeled VCO1 through VCO4.

Each VCO may be coupled to its corresponding battery cell and generates a frequency output that is indicative of the voltage across that cell. These frequency signals are routed through respective receivers (RECEIVER 1 to RECEIVER 4), and then to corresponding counters. The counters measure the frequency over a defined sampling period and provide the result to a central Digital Engine. The Digital Engine aggregates the voltage data for each cell and may compute state-of-charge (SOC), detect cell imbalance, or monitor cell-level health through impedance tracking.

A separate Current Sense Resistor may monitor the current flowing into or out of the battery pack. The voltage drop across the current sense resistor is input to a Current VCO, which converts the current to a corresponding frequency. The output of the Current VCO is counted and forwarded to the Digital Engine to determine accumulated charge (i.e., coulombs).

The system 100 also includes a Temperature VCO coupled to a temperature sensor, which outputs a frequency indicative of system or ambient temperature. This frequency is measured by another counter and used by the Digital Engine for temperature compensation and periodic recalibration routines.

A VCO Clock and Sample Time Generator block synchronizes the sampling and counting operations across all VCOs and counters, ensuring that current and voltage values are averaged or measured over the same time interval. In some examples, the averaging may be performed by an ADC. The averaging enables more accurate correlation of instantaneous current and voltage values for impedance calculation, energy estimation, and other battery management tasks.

The Digital Engine functions as the central processing and control unit of the system. It receives the counted output from the cell voltage VCOs, current VCO, and temperature VCO, and performs real-time computations to track coulomb accumulation, calculate SOC, estimate remaining energy, and monitor battery impedance. The Digital Engine may trigger impedance measurements based on step changes in current, validate conditions for such measurements using programmable thresholds (e.g., SOC, temperature, voltage), and update internal models or lookup tables accordingly. In some implementations, the Digital Engine may further interface with external host systems to report diagnostic information, communicate remaining runtime estimates, or initiate safety and balancing protocols. The Digital Engine may be implemented as a microcontroller, digital signal processor, FPGA, or dedicated logic block depending on the system requirements.

The PACK+ terminal shown at the top of the figure corresponds to the positive terminal of the battery pack, the highest voltage node in the battery stack. It serves as the high-side reference for the battery pack and is commonly used in high-side sensing configurations. In such configurations, components like the VCOs and input switches float at high potential relative to system ground, and level shifters or isolation circuits may be used to interface these components with ground-referenced logic. Using PACK+ as the reference enables simplified return path wiring and allows the system to leverage the physical structure of the battery enclosure as a return conductor, thereby improving robustness and reducing system complexity.

Voltage-controlled oscillators (VCOs) are circuits that produce an output frequency based on an input voltage. Current measurement is often performed by using a series resistor (or other means of converting a current to voltage, such as Hall-Effect Sensors) in the current path, such that the voltage at this resistor represents the current through the current path. If the voltage is applied to the VCO input, which could be amplified first for higher system gain, the output of the VCO changes frequency as the current changes. Because the VCO can be designed to have a highly linear transfer function, the output frequency of such VCO is a direct representation of the resistor current at all times.

By connecting the output of the VCO to a counter, the counter may accumulate the charge that is passing through the resistor without sampling time, and averaging the input signal or the output of the VCO. As the current varies, so does the frequency of the VCO, and the variation is captured by the counters. Because the VCO may have a finite response to a variable input, a low pass filter may be implemented at the input to the VCO such that the high frequency does not pass through, and therefore, the VCO can be working within the VCO's limitations and avoiding induced error for input frequencies beyond VCO response limits.

VCOs that produce a zero frequency at a zero input, inherently have low resolution at low input values. Systems utilizing this type of VCO also have low resolution at low inputs, resulting in low accuracy. For this, the VCOs may start at a pedestal output frequency, where the zero input generates a measurable frequency, designed to provide practical implementations and high resolution even at low input values.

With this, a sampling system may be specified to subtract this frequency, which represents the zero-input frequency, leaving the net frequency representation of the input, which after subtraction, can go down to zero at the zero input, while maintaining a high resolution even at low input values. This sampling time is not the same as a conventional sample time. For example, there is no dependency on the actual sample time, as long as the same sample time is used to measure the zero-input frequency. Once the zero frequency is subtracted, the result can be accumulated by adding the result to the remaining coulomb register, or accumulator, to represent the total accumulation.

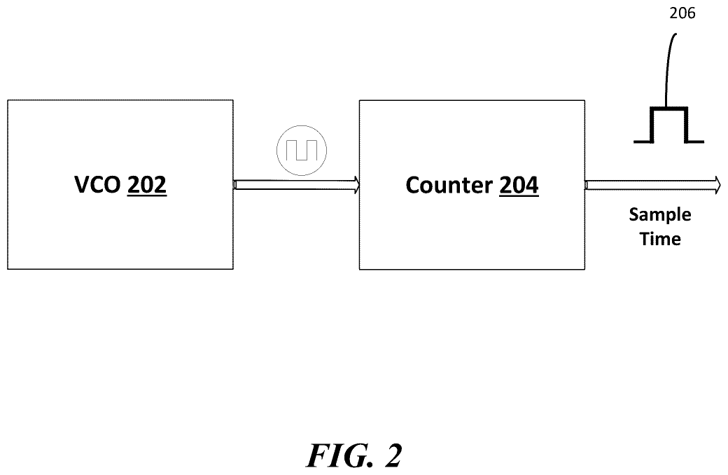

FIG. 2 is a block diagram illustrating an example of a sample time generation circuit 200 configured to produce a timing signal used to synchronize sampling across multiple VCO-based measurement channels, in accordance with various aspects of the present disclosure. The circuit includes a Voltage-Controlled Oscillator (VCO) 202 that is substantially identical to the measurement VCOs used for voltage, current, or temperature sensing. This VCO 202 is selected to have a similar temperature coefficient and minimal sensitivity to input voltage or power supply variations, thereby ensuring that its behavior closely matches the VCOs used in the main sensing channels. The use of a matching VCO 202 helps maintain synchronization and consistency across all time-domain operations in varying environmental conditions.

The output of the VCO 202 is connected to a counter 204 that may include a preset overflow threshold. This counter may be implemented within a microcontroller unit (MCU) or as part of a dedicated digital logic block. Once the counter 204 reaches its preset threshold value, it generates a timing pulse, which defines the sample time interval. This pulse may be used to initiate or synchronize measurement events across the system, ensuring that all counters sampling VCO outputs (for voltage, current, and temperature) operate over the same defined period.

The output timing pulse 206 represents the periodic sample time signal generated by this subsystem, which can be used to accumulate charge, calculate average current or voltage, and maintain precise correlation between voltage and current readings for impedance or energy estimation.

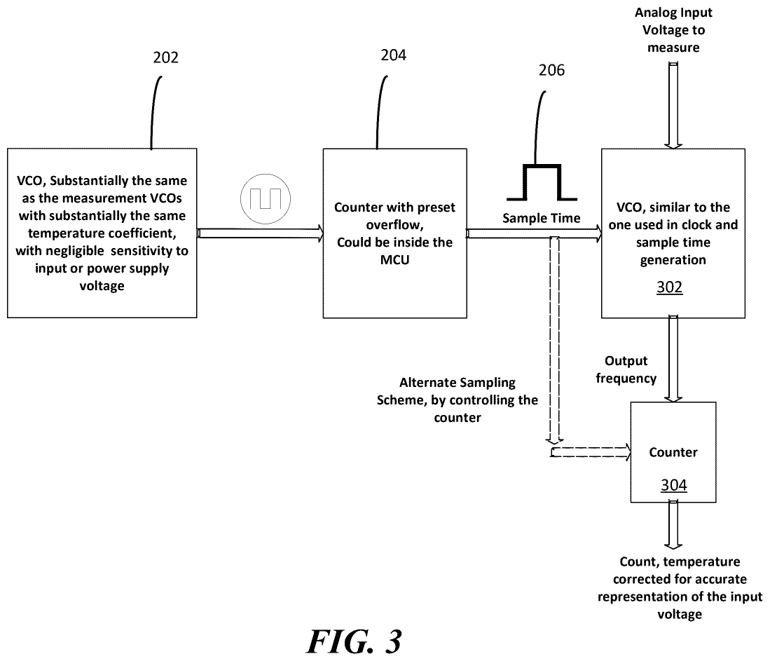

Various aspects of the present disclosure provide a synchronized sampling architecture to ensure accurate voltage measurements across all battery cells and current sensing circuits. FIG. 3 is a block diagram illustrating an example of a measurement subsystem that uses a matched VCO-based sample time generator to coordinate the timing of frequency-based voltage measurements, in accordance with various aspects of the present disclosure.

The system includes a reference VCO 202, which may be substantially the same as the measurement VCOs used elsewhere in the system. The reference VCO 202 is selected for its low sensitivity to power supply voltage and for having a temperature coefficient substantially matching that of the measurement VCOs. This ensures that timekeeping and measurement VCOs are similarly affected by environmental conditions.

The output of VCO 202 is input to a first counter 204 with a preset overflow threshold. The first counter 204, which may reside inside a microcontroller (MCU), generates a sample time pulse 206 when the first counter 204 reaches the preset value. This sample time pulse serves as a synchronization signal for the rest of the measurement circuitry. As shown in FIG. 3, an analog input voltage to measure is provided to a measurement VCO 302, which is similar in construction to the reference VCO 202. The measurement VCO 302 converts the analog voltage to a frequency output. The frequency output from VCO 302 is sent to a second counter 304, which accumulates the signal over the defined sample time generated by the first counter 204. The sample time signal ensures that the counter 304 counts only for the predefined duration, aligning the timing of voltage measurements across all channels.

In some examples, an alternate sampling scheme may indicate that the second counter 304 may be configured or controlled to implement different sampling intervals depending on application requirements or system state. The final count output from the second counter 304 may be temperature-corrected to provide an accurate digital representation of the analog input voltage. The use of matched VCOs 202 and 302 and synchronized sample time generation ensures the system maintains high accuracy across varying environmental conditions.

Because the ambient temperature is not fixed, the battery management system (BMS) integrated circuit (IC) can also produce self-heating, and performance of the VCOs can change over temperature (even with temperature correction circuits), a remedy to decrease the temperature related issues and inaccuracies is to occasionally take a new measurement of the zero-input current signal and update this number for future use.

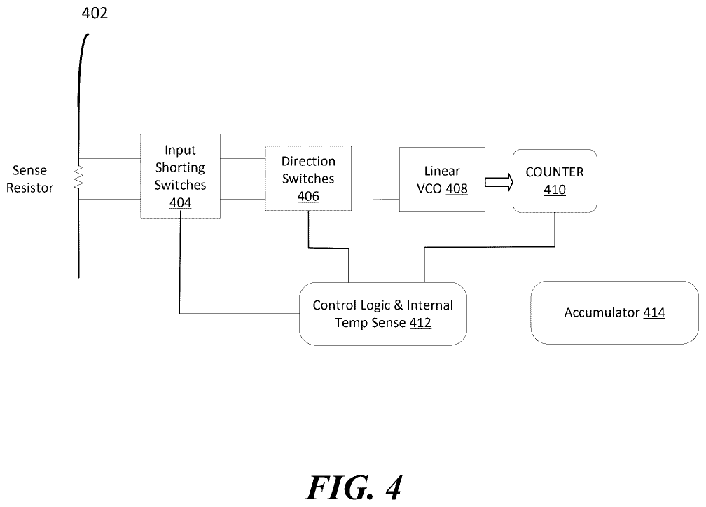

FIG. 4 illustrates an example of a VCO-based charge accumulation subsystem configured to implement such periodic recalibration and bidirectional charge detection, in accordance with various aspects of the present disclosure. As shown in FIG. 4, a sense resistor 402 may detect the current flowing through a battery circuit. The voltage across the sense resistor 402 is routed to a set of input shorting switches 404, which may be activated under the control of logic circuitry to force a known zero-input condition. This allows the system to measure and record the zero-input frequency of the VCO and account for temperature drift or offset.

The voltage signal then passes through a set of direction switches 406, which dynamically reverse the polarity of the input based on the detected direction of current flow. This ensures that the linear VCO 408 receives a consistent polarity input, regardless of whether the current is flowing in a charging or discharging direction. The output of the linear VCO 408 is a frequency that represents the magnitude of the sensed current, and this frequency is counted by a counter 410.

A control logic block 412, which includes or communicates with an internal temperature sensor, orchestrates the timing of the zero-input measurements, controls the direction switches, and determines whether to add or subtract from the total coulomb count based on current direction. The logic tracks whether the measured frequency is above or below the zero-input baseline, and flips the polarity accordingly. An accumulator 414 receives the resulting charge data from the counter and maintains a net charge value over time. This architecture enables accurate and drift-resistant coulomb counting by compensating for temperature changes and maintaining symmetry between charge and discharge operations.

The measurement may be periodically or dynamically updated. For example, the measurement may be updated based on fixed time intervals and/or temperature change. The inputs to the VCO can be shorted using transistors as switches to take a zero-input measurement. To reduce the loss of the signal during the measurement, the sampling system may add one sampling interval measurement as a replacement for the lost period.

The lost period is an example of a period where the inputs were shorted together during the zero-input frequency measurement update, and the actual coulombs were not measured and therefore lost. Assuming the current did not substantially change during this time, and that the intervals at which the new zero count is taken are much shorter than the actual measurement period, this estimation of lost coulomb will eliminate measurable loss of data and still produce highly accurate results.

Additionally, current measured in the discharge direction can be subtracted from the accumulated coulomb total to provide a substantially accurate indication of the remaining charge within the battery. To ensure that the gain of the system remains symmetrical regardless of the direction of current flow, a set of direction switches may be employed to reverse the input polarity to the VCO. This configuration causes the system to generate the same output frequency for a given magnitude of current, whether the current is flowing into the battery (charging) or out of the battery (discharging).

The control logic block, which is responsible for monitoring and managing the charge accumulation process, continuously evaluates the VCO output relative to a known zero-input frequency. When the measured frequency drops below the stored zero-input value, the control logic can infer a reversal in current direction and activate the direction switches accordingly. The logic circuit maintains an internal record of the current direction and, based on this information, determines whether to add the counted value to the total coulomb register or subtract it. This ensures that charge accumulation accurately reflects both charging and discharging activity.

The proposed system, which uses a VCO and associated digital components to perform charge accumulation, enables an accurate and repeatable measurement of coulombs over time. This architecture supports near-continuous integration of charge and allows for highly precise estimation of the battery's state of charge. Unlike conventional approaches that depend on sampled current measurements combined with averaging over time, the present system inherently integrates current flow in real time without relying on external sample clocks or fixed integration windows.

This natural integration of charge substantially eliminates dependency on sample timing, which is a primary source of inaccuracy in many traditional coulomb counting systems. Because the system calculates charge directly based on the number of electrons passing through a known resistance, no modeling or compensation for time-domain errors is required.

Conventional systems often rely on complex battery modeling to estimate remaining charge. These models may include voltage discharge curves, temperature correction factors, and other behavioral approximations that attempt to compensate for system inaccuracies. However, such models are inherently sensitive to error and often require continuous adjustment to remain valid across varying environmental and operational conditions.

In contrast, the present disclosure enables a more direct and reliable estimation of battery charge by focusing solely on the actual measured coulombs. This reduces or eliminates the need for modeling battery voltage profiles, temperature behavior, or aging compensation algorithms. The result is a streamlined system architecture that not only improves robustness and accuracy but also reduces susceptibility to error from parameter drift, environmental changes, or device-to-device variability.

Because this system depends only on actual coulomb count, determining the total capacity of a given battery, represented as X, may be accomplished by recording the cumulative charge during a complete charge cycle, from empty to full. Once this baseline value is obtained, it can be applied to future battery packs by scaling it in proportion to the gain of each individual system. For instance, if a reference unit recorded 2 million counts/second with a known current during a full charge, and a new system has a gain of 2.2 million, then the adjusted capacity count for the new system becomes X′=(2.2/2.0)×X. This process enables accurate calibration during production, allowing each battery management system (BMS) integrated circuit to be programmed with a unique gain value stored in nonvolatile memory. That gain value is later used in the field to apply system-specific adjustments to the accumulated charge total.

In some implementations, the system may also calculate and report the average used charge over a selected time interval, such as seconds or minutes. This moving average can be used to estimate the remaining usage time based on current consumption trends. For example, dividing the remaining charge by the recent average usage provides a value for remaining time in average time units. That value can later be translated into seconds or minutes by factoring in the system's known sampling characteristics. However, it should be noted that conventional systems with inaccurate coulomb tracking will also yield unreliable average usage values, which in turn undermines the accuracy of remaining time estimates. By contrast, the high-fidelity coulomb counting achieved in the present system enables more meaningful reporting of both charge and expected runtime across a wide range of applications, including notebook computers, electric vehicles, and other battery-powered devices.

The techniques described thus far provide a robust framework for accurate coulomb counting, temperature-aware calibration, and direction-sensitive charge tracking. However, to further enhance the precision of remaining energy estimation and support broader battery health monitoring, additional techniques may be incorporated into the system. These include advanced impedance estimation and simultaneous multi-cell voltage measurement (which is a major enabler for impedance measurement), and together enable more accurate determination of open circuit voltage (OCV), battery aging, and remaining runtime predictions.

To accurately estimate the remaining energy of a battery, it is necessary to determine the amount of available charge at specific points along the battery's open circuit voltage (OCV) curve. Because the OCV curve is continuous and theoretically consists of infinitely many points, a practical approach involves discretizing the curve into a finite number of segments. Each segment can be approximated as a small rectangle, where the area of the rectangle represents the energy associated with a specific charge interval and its corresponding voltage. The total remaining energy can then be approximated by summing the areas of these rectangles. The resolution of the approximation depends on the number and size of the segments, which can be selected based on the accuracy required and the system's available computational and memory resources.

In one example, a lookup table may be created to store the precomputed values associated with these discrete rectangles. The size and granularity of the table may be limited by available memory and processing constraints. This energy characterization can be dynamically updated during each charge cycle, which is particularly advantageous since the effective battery capacity can change over time due to factors such as aging and temperature. By updating the table based on newly accumulated charge and voltage data during the charging process, the system can refine its estimate of the battery's capacity and energy availability. Accurate energy estimation requires knowledge of the OCV at various points over SOC, which in turn necessitates a method to extract OCV from loaded terminal voltage and calculated impedance.

During active charging or discharging, the measured battery voltage does not reflect the true open circuit voltage, as it is affected by both the instantaneous current and the internal impedance of the battery. Therefore, it is critical to estimate the battery's impedance in order to correct the loaded voltage and recover a reliable approximation of the OCV. Since direct real-time measurement of battery impedance is generally not feasible in typical operating environments, the following approach is provided to estimate impedance using system data.

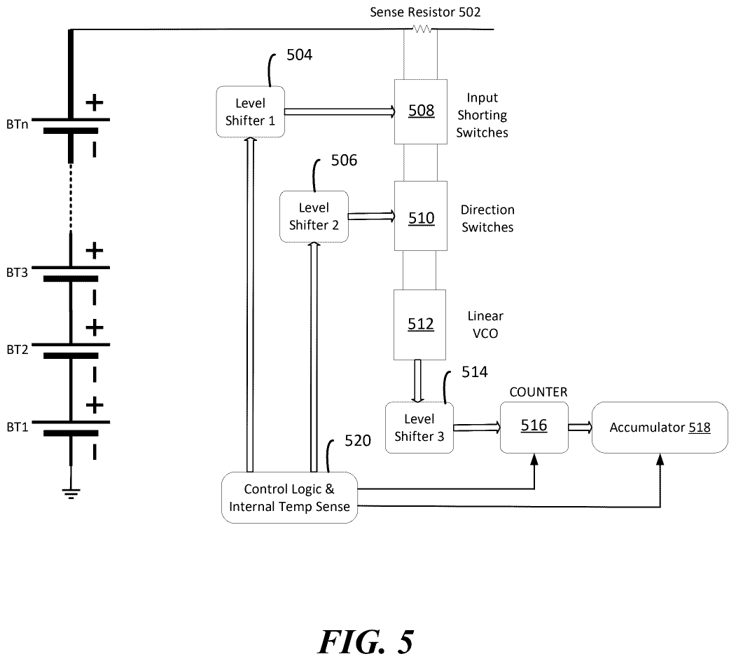

FIG. 5 illustrates a high-side coulomb counting and calibration architecture, in accordance with various aspects of the present disclosure. The architecture of FIG. 5 may be specified for precise charge accumulation, zero-input offset correction, and bidirectional current handling across a stacked battery pack. This configuration may be well-suited for applications where the current sense resistor is placed on the high-voltage side of the battery stack, such as in electric vehicles or industrial battery modules, where minimizing ground return complexity and optimizing mechanical layout are critical.

As shown in the example of FIG. 5, the battery stack includes a group of series-connected cells labeled BT1 through BTn, representing individual lithium-ion or equivalent electrochemical cells. The top of the stack connects to the sense resistor 502, which is positioned between the battery positive terminal and the system's output rail. The sense resistor 502 may develop a differential voltage proportional to the instantaneous current flowing into or out of the battery pack.

To accommodate the high-side location of the sense resistor, the measurement circuitry floats at the battery potential. Accordingly, the system includes three level shifters—504 (Level Shifter 1), 506 (Level Shifter 2), and 514 (Level Shifter 3), which electrically isolate and translate signals between the ground-referenced control logic block 520 and the floating high-side domain. These level shifters 504, 506, and 514 allow the centralized control logic to safely and effectively coordinate high-voltage measurement operations while remaining electrically isolated from the battery voltage.

The input shorting switch block 508 includes a set of transistors that can short the input to the linear voltage-controlled oscillator (VCO) 512, thereby forcing a known zero-current condition. This enables the system to measure the VCO's 512 baseline or pedestal frequency at zero input, which may shift over time due to temperature changes, drift, or long-term aging. Periodic recalibration of this zero-input frequency ensures that subsequent charge accumulation is both accurate and drift-compensated.

The direction switch block 510 reverses the polarity of the signal applied to the VCO input depending on the direction of current flow. By reorienting the signal to maintain a consistent polarity, the system ensures that the VCO output frequency is symmetrical with respect to current magnitude, independent of direction. This symmetry simplifies downstream processing and allows the counter 516 to track frequency changes without regard to signal inversion.

The linear VCO 512 converts the analog voltage derived from the sense resistor into a digital pulse train whose frequency is linearly proportional to the magnitude of the input current. The output of the VCO is routed through Level Shifter 3 (514) to the counter 516, which accumulates the frequency pulses over time. The counter's output represents the total number of coulombs that have passed through the sense resistor during operation.

The output of the counter 516 feeds into an accumulator 518, which maintains the net coulomb count by adding or subtracting values based on the current direction. The control logic block 520 tracks whether the system is in charging or discharging mode by comparing the measured VCO frequency to the stored zero-input value. When the frequency exceeds the pedestal value, the system adds the corresponding charge; when it falls below, it subtracts it. This bidirectional tracking ensures a highly accurate representation of the actual state of charge (SOC) of the battery pack.

The control logic and internal temperature sense block 520 may orchestrate the operation of the system. The control logic 520 manages the timing of recalibration events, triggers polarity switching based on current direction, applies temperature compensation as needed, and determines when to reset or synchronize counters. In production environments, this control logic block 520 may also handle gain calibration by applying known charge patterns and adjusting system coefficients stored in nonvolatile memory.

As discussed, the architecture of FIG. 5 shows a high-side current and coulomb sensing configuration. The input stages, such as the input shorting switch 508, direction switch 510, and voltage-controlled oscillator (VCO) 512, are placed on the high side of the circuit and float relative to the top of the battery stack. These components are electrically isolated from ground and referenced to the high-voltage node at the top of the series-connected battery cells BT1 through BTn. The control logic and internal temperature sense block 520, which operates at system ground potential, interfaces with the high-side components through three dedicated level shifters. Specifically, Level Shifter 1 (504) drives the input shorting switch 508, Level Shifter 2 (506) controls the direction switch 510, and Level Shifter 3 (514) couples the output of the VCO 512 to the counter 516. The functional behavior of this circuit mirrors the previously described low-side implementation; however, the placement of the sense resistor 502 on the high side offers a significant mechanical and electrical advantage. By doing so, the system may use the device enclosure or body as the current return path, thereby eliminating the need for a dedicated ground wire. This approach improves robustness, reduces overall system cost, and simplifies integration in space-constrained or high-voltage environments.

Overall, the architecture shown in FIG. 5 may be integrated into a battery management system (BMS) across a wide range of voltage and current operating conditions, offering a robust solution for coulomb counting, direction-aware current tracking, temperature compensation, and drift mitigation. Beyond charge tracking, the same architecture may support additional advanced battery diagnostics and analytics, including impedance-based health monitoring and open circuit voltage (OCV) estimation, critical parameters for accurate state-of-health (SOH) and remaining energy determinations.

One such application is the estimation of internal battery impedance, which plays a critical role in accurately determining OCV during active load and charge conditions, and in tracking degradation over the battery's lifecycle. Generally speaking, impedance can be estimated as the ratio of a change in voltage to a change in current (ΔV/ΔI). Since modern BMS platforms continuously monitor both current and cell voltages, a detected step in current can be used to trigger a recalculation of impedance.

To maximize precision, it is highly advantageous to measure the voltages of all battery cells simultaneously, rather than using a time-multiplexed analog-to-digital converter (ADC) scheme. Time-multiplexed architectures introduce latency between measurements, requiring compensation algorithms to estimate what the voltage of each cell was at a common current point. This approximation process often leads to inaccuracies, particularly during dynamic load conditions. By contrast, the present disclosure leverages synchronized, simultaneous sampling of all cell voltages and the system current, ensuring that every cell's voltage is measured under the same exact load condition. This eliminates the need for post-sampling normalization and substantially improves the precision of the impedance estimation.

Once a step in current is detected, such as a sudden load activation or deactivation, the system evaluates whether all relevant parameters fall within predefined thresholds that make the measurement valid and meaningful. These thresholds may include the magnitude of the current step, battery temperature, cell voltage levels, and optionally, state of charge. If all conditions are satisfied, the system calculates impedance for each cell using the change in voltage divided by the change in current, based on the pre-step and post-step measurement sets.

The BMS may then log these impedance values, compare them to previous measurements, and use the results to assess the health of each individual cell. A significant increase in impedance over time may indicate degradation or aging of the cell, while a deviation from pack-average values may signal the presence of an outlier or defect. This information can be reported to the host system or used internally by the BMS to trigger replacement warnings or system shutdown.

In addition to its role in health diagnostics, impedance is also used to improve OCV estimation. During discharge, the OCV may be approximated by adding the product of current and impedance to the loaded voltage. Conversely, during charging, the OCV is determined by subtracting the product of current and impedance. Accurate impedance estimation therefore directly improves the system's ability to compute remaining energy by allowing it to reference the correct position on the OCV versus SOC curve.

This information can then be applied to a lookup table or mathematical model that relates OCV to remaining energy, enabling the system to make real-time predictions of energy availability under varying load conditions. By eliminating errors introduced by relying on terminal voltage alone, this approach ensures that remaining energy estimates remain accurate even during loading conditions.

In some implementations, the system may be designed to apply a stimulus current precisely when an impedance measurement is needed. The BMS can capture a baseline cell voltage reading, initiate a known load or current pulse, and then capture a second set of voltages during the applied load. This controlled ΔI event allows the system to calculate ΔV across all cells and perform an intentional and highly repeatable impedance measurement. The decision to initiate such a controlled event may be based on factors such as temperature, SOC, or time since the last measurement.

As an alternative or complement to OCV-based energy estimation, the system may use a direct correlation between remaining coulombs and remaining energy for specific battery chemistries. A characterization table or model may be built for each battery family, allowing the system to estimate energy based solely on coulomb count. This method may be less precise at the extremes of the temperature range but offers a fast and lightweight estimation method within the typical operating window.

Within moderate temperature ranges, such as 10° C. to 40° C., the effect of temperature on energy estimation tends to be approximately linear. In such cases, a simple temperature compensation function or correction table can be applied to adjust the remaining energy estimate without the need for real-time impedance or voltage analysis. For high-accuracy applications operating outside of this range, more complex compensation algorithms may be used, or the system may tolerate a slight increase in error as a tradeoff for reduced processing overhead.

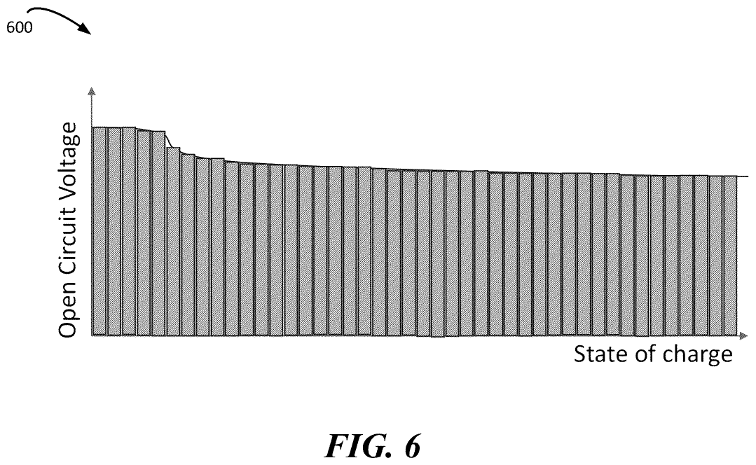

FIG. 6 illustrates an example 600 of partitioning a battery's state of charge (SOC) versus open circuit voltage (OCV) profile, in accordance with various aspects of the present disclosure. This profile may be used to estimate the remaining energy in a battery, particularly in systems that rely on indirect measurements during charging or discharging.

In FIG. 6, the vertical axis represents open circuit voltage (OCV), while the horizontal axis represents state of charge (SOC), typically ranging from 0% (fully depleted) to 100% (fully charged). The curve shown reflects a typical discharge profile for a lithium-ion cell, where the OCV gradually declines as the SOC decreases. The initial portion of the curve may include a steep voltage drop, followed by a relatively flat region, and finally a tail-off as the battery approaches full discharge.

To make use of this curve in real-time estimation, the continuous SOC-OCV relationship is discretized into a series of narrow vertical segments, each shown as a shaded rectangle. Each rectangle approximates a small region of the curve using a constant voltage value across a defined SOC interval. The area of each rectangle (voltage multiplied by charge) represents an incremental portion of the battery's stored energy.

By summing the areas of these rectangles from the current SOC point to the end of the curve, the system can approximate the remaining energy in the battery. The resolution of the estimation depends on the width of each SOC partition: narrower rectangles yield higher accuracy, at the cost of increased memory and processing requirements. This partitioned model can be stored as a lookup table or calculated dynamically during operation.

The approach depicted in FIG. 6 enables efficient and accurate energy estimation even in embedded systems with limited computational resources. It also provides a framework for dynamically updating the battery model in response to environmental factors such as temperature or aging, by adjusting the rectangle heights (voltage values) or widths (charge intervals) based on real-time measurements.

As discussed, various aspects of the present disclosure provide a robust, accurate, and scalable approach to coulomb counting, impedance estimation, and remaining energy calculation for battery-powered devices. By leveraging a voltage-controlled oscillator (VCO)-based architecture with floating high-side sensing, dynamic direction switching, periodic zero-input calibration, and synchronized voltage and current sampling, the system eliminates many of the errors inherent in conventional approaches. The disclosed architecture supports both high-resolution energy tracking and advanced diagnostics, including impedance-based health assessment and aging detection. These capabilities make the system particularly well-suited for modern battery management systems (BMS), which must balance precision, safety, and efficiency under increasingly demanding operational requirements.

The battery management system described herein may be integrated into a wide range of applications, including electric vehicles (EVs), hybrid vehicles, e-bikes, energy storage systems, uninterruptible power supplies (UPS), aerospace and aviation power systems, portable medical equipment, power tools, and consumer electronics such as laptops and smartphones. In each of these applications, the BMS is responsible for monitoring cell voltages, balancing charge, estimating remaining runtime, preventing overcharge and over discharge, and reporting state-of-health metrics, all of which are supported by the precise coulomb counting and impedance-aware architecture disclosed in this specification.

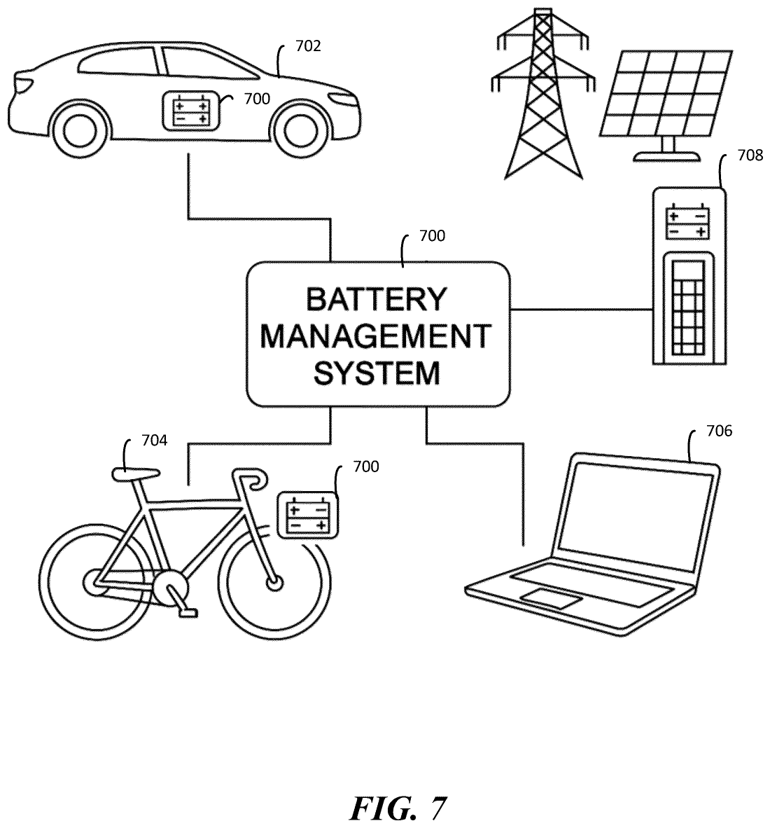

FIG. 7 illustrates representative use cases for a battery management system (BMS) 700, in accordance with various aspects of the present disclosure. The BMS 700 may incorporate one or more architectures or components described with reference to FIGS. 1-5. In some examples, the BMS 700 may interface with several different application domains via electrical connections. These connections represent the integration of the sensing, monitoring, and control functionalities disclosed in this specification into each system's power infrastructure.

In some examples, the BMS 700 may be embedded in or adjacent to the battery pack of an electric vehicle (EV) 702. In this configuration, the BMS 700 performs coulomb counting to track charging and discharging cycles, estimates remaining range based on real-time current consumption, and detects impedance changes that may signal cell aging or degradation. The high-side sensing architecture shown in earlier figures enables direct current measurement while minimizing chassis wiring complexity, which is particularly valuable in automotive environments.

Additionally, or alternatively, an electric bicycle (e-bike) 704 may use the BMS 700. These compact battery-powered systems benefit from the accurate, lowcost and efficient nature of the VCO-based BMS design, allowing for highly accurate runtime estimation, temperature-adjusted charge tracking, and simple production calibration even in physically constrained enclosures. In some examples, a laptop computer 706 represents consumer electronics applications where accurate battery reporting, safety, and long-term cycle health are paramount. The laptop computer 706 can use the BMS 700 to compute average energy usage, predict shutdown time, and dynamically adjust performance based on remaining energy estimates. Temperature-compensated coulomb tracking also improves battery life estimation under high-performance usage scenarios.

Additionally, or alternatively, a stationary energy storage system 708 (such as a wall-mounted residential or commercial battery unit) may use the BMS 700. The stationary energy storage system 708 may be connected to solar panels and/or a power grid interface. In this setting, the BMS 700 can help manage charge balancing across large packs, estimate energy availability for home or grid delivery, and monitor for performance loss over time using impedance-based health diagnostics. It may also coordinate controlled current loads for impedance calibration during off-peak periods.

The BMS 700 may represent either a discrete hardware module embedded directly into each device or a distributed BMS platform where multiple modules communicate with a central processor. In all implementations, the system architecture described herein, with high-side current sensing, VCO-based accumulation, direction-sensitive logic, and OCV-based energy modeling, can be implemented using scalable analog and digital hardware for integration across diverse voltage, current, and environmental conditions.

While FIG. 7 illustrates representative examples, including an electric vehicle 702, an e-bike 704, a laptop 706, and a stationary energy storage system 708 connected to solar and grid infrastructure, the integration of the battery management system is not limited to these specific devices. Other implementations are fully contemplated within the scope of the present disclosure. These may include, for example, uninterruptible power supplies (UPS), medical devices, power tools, autonomous drones, electric scooters, robotic systems, aerospace applications, marine power systems, and portable industrial equipment. In each of these systems, the disclosed BMS architecture may be tailored to meet specific performance, safety, or environmental constraints while maintaining the core functionality described herein. The modularity of the architecture, including scalable sensing, programmable logic, and temperature-compensated calibration, makes it suitable for both low-power embedded devices and high-voltage industrial platforms.

As discussed, the present disclosure relates to a system and method for estimating battery impedance and remaining energy in a battery system comprising a group of battery cells. The system periodically measures the current and voltages of all battery cells in the group over a defined time period, and determines a present current value by averaging the measurements during that period. A step change in current is detected by comparing the present value to one or more previously stored current values. When a validated step change is identified, an impedance measurement event is initiated.

To improve accuracy, the system stores a last set of current and voltage measurements prior to the step change and determines whether the step exceeds a predefined threshold. Additional validation conditions may include voltage range, current magnitude, and battery temperature. Once validated, the system calculates an impedance value for each battery cell by dividing the respective change in voltage by the corresponding change in current, and stores the impedance values. These values may be presented to a user prior to subsequent measurement cycles via a user interface. Impedance measurement events may also be triggered based on other parameters such as the state of charge (SOC), open circuit voltage (OCV), measured voltage, temperature, or a current step.

The system supports configurations where the battery cells are connected in series and includes the ability to determine SOC values using either a lookup table or a curve fitting function. The lookup table may map averaged OCV values to corresponding SOC values, where the OCV is derived from measured current, voltage, and impedance. Alternatively, the OCV vs. SOC profile may be segmented and used to identify a slope region, from which a more precise SOC value can be calculated based on the system's position on the curve. In some examples, the SOC value is determined directly via a curve fitting function that models the open circuit voltage profile for a given battery chemistry or configuration.

Curve fitting is a mathematical technique used to approximate the behavior of a system by applying a formula that represents a continuous curve. In the context of battery systems, curve fitting can be used to model the relationship between variables such as OCV and SOC. Rather than relying on discrete lookup tables, which store precomputed values for specific points, curve fitting provides a continuous function that can estimate any point along the curve with high resolution.

A curve fitting function may take the form of a simple linear equation, such as y=mx+b, where m is the slope and b is the intercept. More commonly, especially in systems where the battery voltage-to-SOC relationship is nonlinear, a polynomial function is used. For example, a curve may be defined as: y=aₙxⁿ+aₙ₋₁xⁿ⁻¹+ . . . +a₂x²+a₁x+a₀, where x represents the independent variable (e.g., SOC or voltage), y is the predicted value (e.g., OCV), and a₀ through an are coefficients derived from historical or experimentally observed battery behavior.

The complexity of the curve fitting function depends on how closely the mathematical function needs to match the actual battery behavior. A battery with a flat discharge curve may require only a low-order polynomial, while more nonlinear systems may require higher-order polynomials or exponential/logarithmic models.

The advantage of curve fitting in battery management systems is that it allows the control circuit to compute precise intermediate values of SOC or energy without needing to interpolate between table entries. This results in faster, more memory-efficient calculations and supports smoother, real-time estimation of battery health, capacity, and remaining runtime.

The system may also perform controlled impedance measurements by initiating a known load, capturing a first set of voltage measurements before the load, and a second set during the load, then calculating impedance values based on the voltage difference and known current change. Furthermore, the system can reference a pre-characterized table that relates remaining coulombs to remaining energy values for a given battery type. The resulting energy value may be further adjusted based on a temperature-dependent correction profile associated with the given battery type, allowing for more accurate energy estimation across a range of operating temperatures.

The specific chemistry and manufacturing process used in the production of a battery directly determine its electrical characteristics, performance behavior, and overall specifications. Parameters such as voltage profile, capacity, internal resistance, thermal response, and aging behavior are all influenced by factors including electrode composition, electrolyte formulation, separator design, and cell construction methods. Batteries that are produced using the same chemistry and follow the same manufacturing process will exhibit substantially similar electrical and thermal properties and may therefore be classified as belonging to the same battery type. This classification enables standardized modeling, performance prediction, and control strategies to be applied across all batteries of that type, which is particularly useful for developing accurate state-of-charge and remaining energy estimation algorithms, as well as implementing temperature-based correction profiles.

The described features may be implemented in a battery monitoring system that includes a current sensor, a plurality of voltage sensors, one for each battery cell, one or more memory units to store historical and real-time data, and a control circuit that executes the described methods. This architecture enables highly accurate, real-time monitoring of battery impedance, state of charge, and remaining energy, and is suitable for integration into a wide range of battery-powered applications including electric vehicles, energy storage systems, portable electronics, and medical devices.

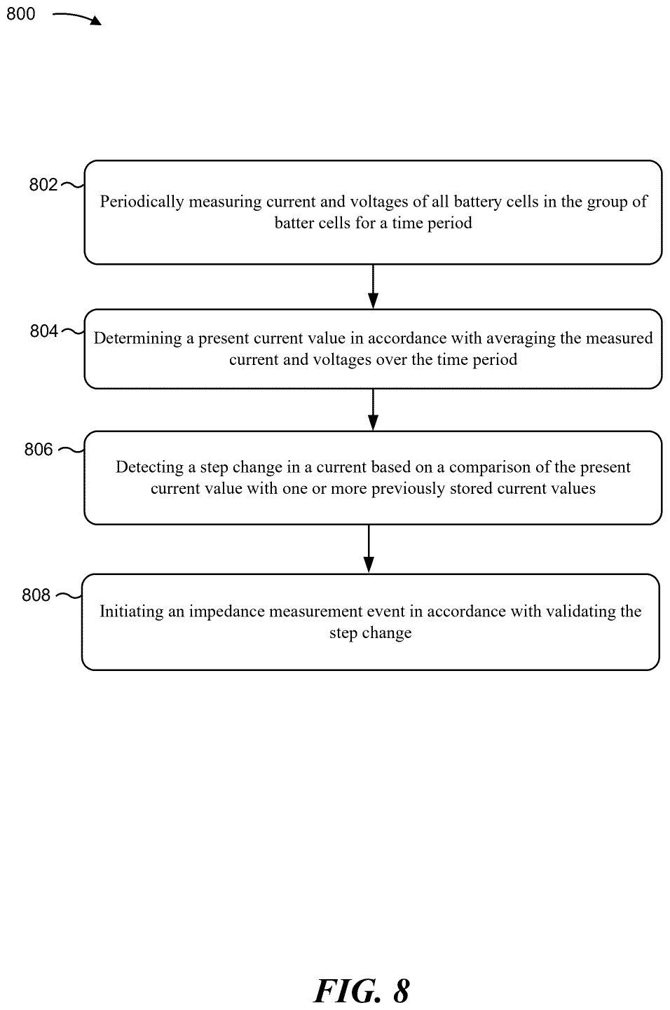

FIG. 8 is a block diagram illustrating an example of a process 800 for estimating battery impedance and remaining energy in a battery system including a group of battery cells, in accordance with various aspects of the present disclosure. In some examples, the process 800 may be performed by a battery monitoring system, such as the system described with reference to FIGS. 1 through 7, which includes one or more current sensors, voltage sensors, memory units, and a control circuit configured to carry out the steps described herein.

The process 800 begins at block 802 by periodically measuring current and voltages of all battery cells in the group of battery cells over a predefined time period. In some examples, the measurements may be performed simultaneously to ensure time alignment between current and voltage data across all cells. At block 804, the process determines a present current value by averaging the measured current and voltages over the same time period. At block 806, the process detects a step change in current by comparing the present current value to one or more previously stored current values. The step change may be indicative of an external load being applied or removed, creating conditions suitable for accurate impedance calculation.

At block 808, the process initiates an impedance measurement event based on validation of the detected step change. This validation may include checking whether the magnitude of the step change exceeds a predefined threshold and whether additional conditions, such as battery temperature, state of charge, or voltage range, are met. Once validated, the control circuit may proceed to store voltage and current snapshots and calculate impedance values for each battery cell by dividing the respective voltage changes by the current change.

In some embodiments, the process may continue with further steps (not shown in FIG. 8) such as storing the calculated impedance values, alerting a user to the updated results, refining state of charge estimation using lookup tables or curve fitting functions, or adjusting remaining energy estimates using a temperature-dependent correction profile associated with a pre-characterized battery type. In some examples, stored energy may be determined via a lookup table or a curve fitting function. The curve fitting function may be used instead of referencing the lookup table.

The process 800 may be performed continuously or on a periodic schedule, and may be triggered by system-defined events, thresholds, or user input. The steps of process 800 provide a foundation for a high-fidelity, real-time assessment of both cell-level impedance and remaining energy, supporting advanced battery management features for electric vehicles, portable electronics, grid-connected storage systems, and other battery-powered platforms.

The foregoing disclosure provides illustration and description, but is not intended to be exhaustive or to limit the aspects to the precise form disclosed. Modifications and variations may be made in light of the above disclosure or may be acquired from practice of the aspects.

As used, the term “component” is intended to be broadly construed as hardware, firmware, and/or a combination of hardware and software. As used, a processor is implemented in hardware, firmware, and/or a combination of hardware and software.

Some aspects are described in connection with thresholds. As used, satisfying a threshold may, depending on the context, refer to a value being greater than the threshold, greater than or equal to the threshold, less than the threshold, less than or equal to the threshold, equal to the threshold, not equal to the threshold, and/or the like.

It will be apparent that systems and/or methods described may be implemented in different forms of hardware, firmware, and/or a combination of hardware and software. The actual specialized control hardware or software code used to implement these systems and/or methods is not limiting of the aspects. Thus, the operation and behavior of the systems and/or methods were described without reference to specific software code—it being understood that software and hardware can be designed to implement the systems and/or methods based, at least in part, on the description.

Even though particular combinations of features are recited in the claims and/or disclosed in the specification, these combinations are not intended to limit the disclosure of various aspects. In fact, many of these features may be combined in ways not specifically recited in the claims and/or disclosed in the specification. Although each dependent claim listed below may directly depend on only one claim, the disclosure of various aspects includes each dependent claim in combination with every other claim in the claim set. A phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (for example, a-a, a-a-a, a-a-b, a-a-c, a-b-b, a-c-c, b-b, b-b-b, b-b-c, c-c, and c-c-c or any other ordering of a, b, and c).

No element, act, or instruction used should be construed as critical or essential unless explicitly described as such. Also, as used, the articles “a” and “an” are intended to include one or more items, and may be used interchangeably with “one or more.” Furthermore, as used, the terms “set” and “group” are intended to include one or more items (for example, related items, unrelated items, a combination of related and unrelated items, and/or the like), and may be used interchangeably with “one or more.” Where only one item is intended, the phrase “only one” or similar language is used. Also, as used, the terms “has,” “have,” “having,” and/or the like are intended to be open-ended terms. Further, the phrase “based on” is intended to mean “based, at least in part, on” unless explicitly stated otherwise.

What is claimed:

1. A method for estimating battery impedance and remaining energy in a battery system comprising a group of battery cells, the method comprising:
simultaneously measuring current and voltages of the group of batter cells for a time period;
determining a present current value in accordance with averaging the measured current and voltages over the time period via an analog-to-digital converter (ADC);
detecting a step change in a current based on a comparison of the present current value with one or more previously stored current values; and
initiating an impedance measurement event in accordance with validating the step change.

2. The method of claim 1, further comprising:
storing a last set of measurements of all cell voltages and current prior to the step change;
determining whether the step change exceeds a predefined threshold;
validating one or more additional conditions, the one or more additional conditions including one or more of a voltage range, current magnitude, or battery temperature;
calculating, in accordance with validating the one or more additional conditions, a respective impedance value for each battery cell of the group of battery cells by dividing a respective change in voltage for each battery cell by a respective change in current for each battery cell; and
storing the respective impedance value of each battery cell.

3. The method of claim 2, further comprising initiating a new impedance measurement event in accordance with one or more of a state of charge, the battery temperature, an open circuit voltage, the measured voltage, a predetermined time interval, or a current step.

4. The method of claim 1, wherein the group of battery cells are connected in series.

5. The method of claim 1, further comprising determining stored energy using a lookup table that maps open circuit voltage values to corresponding state of charge values, wherein an open circuit voltage is calculated in accordance with impedance, voltage and current measurements obtained during the time period.

6. The method of claim 5, further comprising:
partitioning the open circuit voltage versus state of charge profile into segments;
identifying a segment where the profile has a measurable slope; and
determining a position on a curve to calculate the corresponding state of charge.

7. The method of claim 1, further comprising determining a state of charge value via a curve fitting function instead of referencing a lookup table.

8. The method of claim 1, further comprising:
initiating a known load on the battery system in accordance with one or more of a state of charge, a battery temperature, an open circuit voltage, the measured voltage, a predetermined time interval, or a load current;
capturing a first set of cell voltage measurements prior to applying the known load;
capturing a second set of cell voltage measurements during application of the known load; and
calculating impedance values using a difference between the first set of cell voltage measurements and the second set of cell voltage measurements, and a known current change.

9. The method of claim 1, further comprising:
referencing a table representing a pre-characterized relationship between remaining coulombs and a remaining energy value for a given battery type; and
adjusting the remaining energy value based on a temperature-dependent correction profile associated with the given battery type.

10. A battery monitoring system for estimating battery impedance and remaining energy in a battery system comprising a group of battery cells, the battery monitoring system comprising:
a current sensor for measuring current flowing through the battery system;
a group of voltage sensors, each measuring a voltage of a respective battery cell in the group of battery cells;
one or more memory units for storing current and voltage measurements; and
a control circuit configured to:
simultaneously measure current and voltages of the group of battery cells for a time period;
determine a present current value by averaging the measured current and voltages over the time period via an analog-to-digital converter (ADC);
detect a step change in current by comparing the present current value to one or more previously stored current values; and
initiate an impedance measurement event in response to validating a load current step.

11. The battery monitoring system of claim 10, wherein the control circuit is further configured to:
store a last set of measurements of all cell voltages and current prior to a load step;
determine whether the step change exceeds a predefined threshold;
validate one or more additional conditions including one or more of a voltage range, a current magnitude, or a battery temperature;
calculate, in accordance with validating the one or more additional conditions, a respective impedance value for each battery cell by dividing a respective change in voltage by a respective change in current; and
store the respective impedance value for each battery cell of the group of battery cells.

12. The battery monitoring system of claim 11, wherein:
the control circuit is further configured to initiate a new impedance measurement event in response to one or more measurement conditions;
the one or more measurement conditions including one or more of selected state of charge, the battery temperature, open circuit voltage, a predetermined time interval, the measured voltage, or a current step.

13. The battery monitoring system of claim 10, wherein the control circuit is further configured to determine stored energy using a lookup table that maps averaged open circuit voltage values to corresponding state of charge values, wherein an average open circuit voltage is calculated in accordance with the voltage, impedance and current measurements obtained during the time period.

14. The battery monitoring system of claim 10, wherein the control circuit is further configured to determine a state of charge value using a curve fitting formula based on a pre-characterized open circuit voltage versus state of charge profile.

15. The battery monitoring system of claim 10, wherein the control circuit is further configured to:
initiate a known load on the battery system in response to a condition that specifies an impedance measurement;
capture a first set of voltage measurements prior to applying the known load;
capture a second set of voltage measurements during application of the known load; and
calculate impedance values based on a voltage difference between the first set of voltage measurements and the second set of voltage measurements, and a measured current change.

16. The battery monitoring system of claim 10, wherein the control circuit is further configured to:
reference a table representing a pre-characterized relationship between remaining coulombs and a remaining energy value for a given battery family; and
adjust the remaining energy value based on a temperature-dependent correction profile associated with the given battery family.

17. A coulomb counting system comprising:
a current sensing element for generating a voltage proportional to current;
an input shorting switch block for shorting an input to a linear voltage-controlled oscillator (VCO) for zero-input calibration, the linear VCO being configured to output a frequency proportional to the input signal;
a counter configured to accumulate the frequency output of the VCO
a direction switch block for maintaining a consistent input polarity to the VCO regardless of current direction;
a control logic circuit operatively coupled to the input shorting switch block, the direction switch block, and the counter; and
a temperature sensor operatively coupled to the control logic circuit.

18. The system of claim 17, wherein the control logic circuit is configured to:
initiate a zero-input measurement by activating the input shorting switch block either at fixed time intervals or in response to detecting a temperature change exceeding a threshold; and
store a zero-input frequency corresponding to the zero-input measurement.

19. The system of claim 17, wherein the control logic circuit is further configured to:
read an output of the counter; and
activate, in accordance with the output being less than zero, the direction switch block to reverse a polarity of the input to the VCO such that the polarity remains consistent regardless of current direction.

20. The system of claim 19, wherein the control logic circuit is further configured to add or subtract the counter output from an accumulator based on the polarity.

21. The system of claim 17, wherein the control logic circuit is further configured to:
output an accumulated coulomb value based on a first time period, and
accumulate coulombs during charging or discharging of a battery from full to empty or vice versa to represent full battery capacity.

22. The system of claim 21, wherein the control logic circuit is further configured to:
accumulate a zero-input count over a predetermined time period to determine a system gain; and
apply a correction factor to a full capacity of a specific unit in accordance with the system gain.

23. The system of claim 21, wherein the coulomb counting system is incorporated in a battery monitoring system and determines the remaining charge of a battery based on the accumulated coulomb value.

24. The system of claim 23, wherein the control logic circuit is further configured to detect when a battery reaches a full charge and update a total coulomb value required to reach full capacity for future state-of-charge estimations.

25. The system of claim 21, wherein:
the accumulated coulomb value is multiplied by a voltage measurement to determine power usage in a power metering application; and
the current sensing element comprises a sense resistor, a Hall-effect sensor, or a magnetic sensor configured to generate a voltage proportional to current flow.
